(19) United States
(12) Patent Application Publication
(10) Pub. No.: US 2013/0228792 A1
(43) Pub. Date: Sep. 5, 2013

(54) SEMICONDUCTOR LIGHT EMITTING DEVICE

(71) Applicant: SAMSUNG Electronics Co., Ltd, Suwon-si (KR)

(72) Inventors: Hyun Wook SHIM, Suwon (KR); Tonk Ik SHIN, Suwon (KR); Nam Sung KIM, Asan (KR); Young Sun KIM, Suwon (KR)

(73) Assignee: SAMSUNG Electronics Co., Ltd., Suwon-si (KR)

(21) Appl. No.: 13/784,916

(22) Filed: Mar. 5, 2013

(30) Foreign Application Priority Data
Mar. 5, 2012 (KR) 10-2012-0022325

(51) Int. Cl. H01L 33/12

(52) U.S. Cl. CPC H01L 33/12
USPC 257/76; 257/99; 257/98

(57) ABSTRACT

A semiconductor light emitting device includes a substrate having a through hole formed in a thickness direction thereof and a conductive nanowire provided in at least a portion of the through hole, and a light emitting structure formed on the substrate and including a first conductive semiconductor layer, an active layer, and a second conductive semiconductor layer.

### CROSS-REFERENCE TO RELATED APPLICATIONS

This application claims the priority under 35 U.S.C. §119 from Korean Patent Application No. 10-2012-0022325 filed on Mar. 5, 2012, in the Korean Intellectual Property Office, the disclosure of which is incorporated herein by reference in its entirety.

### BACKGROUND OF THE INVENTION

1. Field of the Invention

The present invention relates to a semiconductor light emitting device.

2. Description of the Related Art

Generally, a nitride semiconductor has been widely used in a green or a blue light emitting diode (LED) or a laser diode (LD) provided as a light source in a full-color display device, an image scanner, various signaling systems, and a light communications device. The nitride semiconductor light emitting device may be provided as a light emitting device having an active layer which emits various wavelengths of light, including blue light and green light, through a principle by which electrons and holes are recombined with each other.

After the nitride semiconductor light emitting device has been developed, it has been technically developed, such that the range of applications thereof has increased. Therefore, research into nitride semiconductor light emitting devices for use in general lighting apparatuses and as light sources for electrical apparatuses have been conducted. Particularly, according to the related art, a nitride light emitting device has mainly been used as a component used in a low current/low output mobile product. However, recently, the range of applications of nitride light emitting devices has been gradually expanded to a high current/high output apparatus.

Accordingly, research into technology for improving the light emitting efficiency and quality of a semiconductor light emitting device has been actively conducted. More specifically, in order to solve a problem generated due to differences in thermal expansion coefficients and lattice constants between a semiconductor growth substrate and a semiconductor layer grown on an upper surface thereof, a method of forming a buffer layer between the semiconductor growth substrate and the semiconductor layer, or the like, has been employed. In addition, as the range of applications of the nitride light emitting device has been expanded to include the high current/high output field, various attempts to effectively radiate heat generated in a light emitting device to the outside have been made.

### SUMMARY OF THE INVENTION

The present general inventive concept provides a semiconductor light emitting device with an improved light emitting efficiency by alleviating stress between a substrate and a semiconductor layer.

The present general inventive concept provides a semiconductor light emitting device with improved reliability by improving heat radiating characteristics thereof.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor light emitting device including a substrate having a through hole formed in a thickness direction thereof and a conductive nanowire provided in at least a portion of the through hole, and a light emitting structure formed on the substrate and including a first conductive semiconductor layer, an active layer, and a second conductive semiconductor layer.

The conductive nanowire may be formed of at least one of carbon nanotubes (CNT), a nitride semiconductor, and a transparent conductive oxide.

The carbon nanotubes may have a form of a carbon nanotube paste containing a carbon nanotube powder, a binder, and a solvent.

The nitride semiconductor may be at least one of GaN, AlGaN, InGaN, and AlGaInN.

The transparent conductive oxide may be at least one of zinc oxide (ZnO), indium tin oxide (ITO), tin oxide (TO), indium zinc oxide (IZO) and indium tin zinc oxide (ITZO).

The conductive nanowire may cover an inner surface of the through hole while allowing at least a portion of the through hole to have an empty space.

The through hole may include a plurality of through holes, and the plurality of through holes may be spaced apart from each other to form a regular or irregular pattern.

The plurality of through holes may form a linear pattern in which the plurality of through holes may be spaced apart from each other in a single direction.

The through hole may have a cylindrical or a poly-prismatic shape.

The substrate may be formed of at least one of sapphire, SiC, Si, MgAl₂O₄, MgO, LiAlO₂, LiGaO₂, and GaN.

The semiconductor light emitting device may further include a first electrode formed on the first conductive semiconductor layer exposed by etching the second conductive semiconductor layer, the active layer, and at least a portion of the first conductive semiconductor layer; and a second electrode formed on the second conductive semiconductor layer.

A surface opposing a surface of the substrate on which the light emitting structure is formed may be provided as a main light emitting surface.

The semiconductor light emitting device may further include a first electrode formed on a surface opposing a surface of the substrate on which the light emitting structure is formed; and a second electrode formed on the light emitting structure.

The first electrode may contact the conductive nanowire.

The conductive conductive nanowire may fill a portion of the through hole.

The conductive nanowire may contact at least a portion of the first conductive semiconductor layer.

The semiconductor light emitting device may further include a reflective layer interposed between the substrate and the first electrode.

The foregoing and/or other features and utilities of the present general inventive concept may also be achieved by providing a light emitting device package including a terminal unit connected to the semiconductor light emitting device describe above or hereinafter.

The foregoing and/or other features and utilities of the present general inventive concept may also be achieved by providing an electronic apparatus including a control and power supply unit to output a control signal and a power supply to the light emitting device package describe above or hereinafter.

The foregoing and/or other features and utilities of the present general inventive concept may also be achieved by providing a semiconductor light emitting device including a substrate having one or more through holes formed therein and a conductive nanowire provided in at least a portion of the through hole, and a light emitting structure formed on the substrate and one ends of the through holes and including a first conductive semiconductor layer, a second conductive semiconductor layer, and an active layer disposed between the first and second conductive semiconductor layers to emit light.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view schematically illustrating a semiconductor light emitting device according to an embodiment of the present general inventive concept;

FIG. 2 is a cross sectional view schematically illustrating a semiconductor light emitting device according to an embodiment of the present general inventive concept;

FIGS. 3A through 3C are schematic bottom views illustrating a substrate applicable to a semiconductor light emitting device according to an embodiment of the present general inventive concept;

FIG. 4 is a cross-sectional view schematically illustrating a package having the semiconductor light emitting device of FIG. 1 according to an embodiment of the present general inventive concept;

FIG. 5 is a cross-sectional view schematically illustrating a package having the semiconductor light emitting device of FIG. 2according to an embodiment of the present general inventive concept;

FIG. 6 is a cross-sectional view schematically illustrating a package having the semiconductor light emitting device of FIG. 1 according to an embodiment of the present general inventive concept; and

FIG. 7 is a diagram illustrating an electronic apparatus having a light emitting package according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

However, the embodiments of the present general inventive concept may be modified in many different forms and the scope of the general inventive concept should not be limited to the embodiments set forth herein. In addition, these embodiments are provided so that this disclosure will be thorough and complete, and will fully convey the concept of the invention to those skilled in the art. Therefore, in the drawings, the shapes and dimensions of components may be exaggerated for clarity, and the same reference numerals will be used throughout to designate the same or like components.

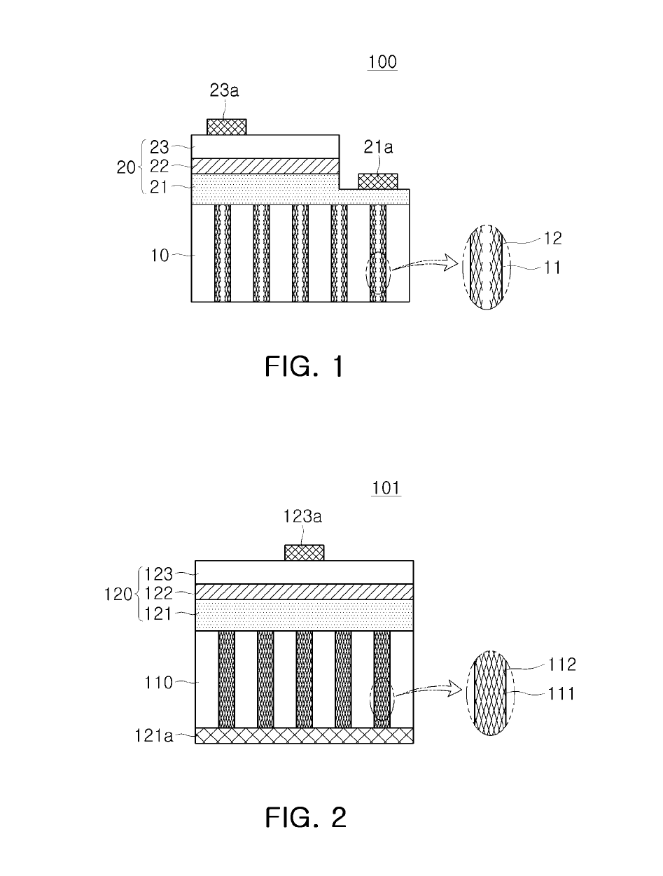

FIG. 1 is a cross-sectional view schematically illustrating a semiconductor light emitting device 100 according to an embodiment of the present general inventive concept.

Referring to FIG. 1, the semiconductor light emitting device 100 according to the embodiment of the present general inventive concept may include a substrate 10, and a light emitting structure 20 formed on the substrate and including a first conductive semiconductor layer 21, an active layer 22, and a second conductive semiconductor layer 23.

The substrate 10 may include a through hole 11 formed in the substrate 10 in a first direction and a conductive nanowire 12 provided in at least a portion of the through hole 11.

In the present embodiment, the first and second conductive semiconductor layers 21 and 23 may be n-type and p-type semiconductor layers and may be formed of a nitride semiconductor material layer. Although the first and second conductive semiconductor layers in the present embodiment are referred to as n-type and p-type semiconductor layers, respectively, the present general inventive concept is not limited thereto. The first and the second conductive semiconductor layers 21 and 23 may be formed of a material having a compositional formula of AlₓIn_{y}Ga_{(1-x-y)}N (where 0≦x≦1, 0≦y≦1, and 0≦x+y≦1). An example of materials having the above-mentioned compositional formula may include GaN, AlGaN, InGaN, or the like.

The active layer 22 is formed between the first and second conductive semiconductor layers 21 and 23 to emit light having a predetermined energy through an electron-hole recombination and may have a multiple quantum-well (MQW) structure, for example, an InGaN/GaN structure, in which quantum well layers and quantum barrier layers are alternately laminated. Meanwhile, the first and second conductive semiconductor layers 21 and 23 and the active layer 22 may be formed using a semiconductor layer growth process such as a metal organic chemical vapor deposition (MOCVD), molecular beam epitaxy (MBE), hydride vapour phase epitaxy (HYPE), or the like.

First and second electrodes 21a and 23a may be formed on the first and second conductive semiconductor layers 21 and 23 to be electrically connected thereto, respectively. As illustrated in FIG. 1, the first electrode 21a may be formed on the first conductive semiconductor layer 21 exposed by etching the second conductive semiconductor layer 23, the active layer 22, and a portion of the first conductive semiconductor layer 21. The second electrode 23a may be formed on the second conductive semiconductor layer 23. In this case, a transparent electrode formed of ITO, ZnO, or the like, may be further provided between the second conductive semiconductor layer 23 and the second electrode 23a in order to improve ohmic contact characteristics therebetween.

Although the first and second electrodes 21a and 23a may be formed so as to face in the same direction as illustrated in FIG. 1, positions and connection structures of the first and second electrodes 21a and 23a may be variously changed according to a design or user preference. The first conductive semiconductor layer 21 may have a first portion having a first thickness and a second portion having a second thickness thinner than the first thickness of the first portion. The first electrode 21a may be disposed on the second portion of the first conductive semiconductor layer 21. The first and second portions of the first conductive semiconductor layer 21 may be disposed on the substrate 10. The active layer 22 and the second conductive semiconductor layer 23 may have the same length as the first portion of the first conductive semiconductor layer 21 in a second direction. The second direction may have an angle with the first direction of the through hole 11. The angle may be a right angle, but the present general inventive concept is not limited thereto.

The substrate 10 may be formed of a material such as sapphire, SiC, Si, MgAl₂O₄, MgO, LiAlO₂, LiGaO₂, GaN, or the like. In this case, sapphire, which is a crystal having hexa-rhombo R3c symmetry, has a lattice constant of 13.001 Å in a C-axis and a lattice constant of 4.758 Å in an A-axis. Orientation planes of the sapphire substrate include a C (0001) plane, an A (1120) plane, an R (1102) plane, and the like. The C plane may be mainly used as a substrate for nitride growth as it facilitates the growth of a nitride film and is stable at a high temperature.

Although not illustrated, a buffer layer formed of an undoped semiconductor layer made of a nitride, or the like, may be interposed in order to alleviate a lattice defect in the light emitting structure grown on the substrate.

The substrate 10 may include at least one through hole 11 formed in the first direction, for example, a thickness direction of the substrate. The through holes 11 may have a circular or a poly-prismatic shape and be provided to have a regular or irregular pattern.

The through hole 11 formed in the substrate 10 may significantly reduce stress generated due to differences in lattice constants and thermal expansion coefficients between the substrate 10 and a semiconductor layer grown on an upper surface of the substrate 10 and alleviate strain in the light emitting structure 20 grown on the substrate 10 to thereby improve light distribution and light emitting efficiency.

Meanwhile, the substrate 10 may include the conductive nanowire 12 provided in at least a portion of the through hole 11. The conductive nanowire 12 may be formed of one of carbon nanotubes (CNT), a nitride semiconductor, and a transparent conductive oxide, and may be formed of a material having high thermal conductivity and electrical conductivity.

The conductive nanowire 12 may be provided to fill an entire portion or a portion of the through hole 11 formed in the substrate 10, and may cover an inner surface of the through hole 11 to allow an empty space to be maintained in the through hole 11, as illustrated in FIG. 1.

The through hole 11 is filled with the conductive nanowire 12 formed of the material having the high thermal conductivity, such that heat generated from the light emitting structure 20 can be easily radiated to an outside thereof through the through hole 11 formed in the substrate 10. Therefore, heat radiating characteristics are improved, and reliability of a light emitting device may be improved.

That is, the semiconductor light emitting device 100 according to the present embodiment may alleviate stress due to differences in lattice constants and thermal expansion coefficients between the semiconductor layer and the substrate through the through hole 11 formed in the substrate 10, and may have an improved heat radiating efficiency through the conductive nanowire 12 provided in the through hole 11.

Carbon nanotubes may be a tubular (cylindrical) new material in which hexagons, each including 6 carbon atoms, are connected to each other to form a tubular shape and are known as carbon nanotubes having a diameter of several to several tens of nanometers, and thus the carbon nanotubes may be usable as one of the conductive nanowires 12. The carbon nanotube may have electrical conductivity similar to that of copper, thermal conductivity similar to that of diamond, the highest in the natural world, and strength one hundred thousand times greater than that of steel. A carbon fiber may be disconnected with a deformation of only 1%, while carbon nanotubes may endure deformation of up to 15%. The carbon nanotubes may have a tension better than that of the diamond.

Carbon nanotubes may have significantly excellent thermal conductivity. As compared to the copper (Cu) having thermal conductivity of about 400 W/mK and aluminum (Al) having thermal conductivity of about 203 W/mK that have been currently known as metals having excellent thermal conductivity, the carbon nanotubes have a higher thermal conductivity of about 3000 W/mK at a temperature of 100K or higher and also have a high thermal conductivity of about 3700 W/mK at a temperature of 100K or less.

Therefore, in a case in which the carbon nanotubes are provided in at least a portion of the through hole 11 formed in the substrate 10, the heat generated in the light emitting structure 20 may be effectively radiated through the substrate 10 due to the high thermal conductivity of the carbon nanotubes. In addition, since the carbon nanotubes have higher light transmissivity than that of a metal, the radiation of heat may be significantly increased, and light absorption may be significantly decreased as compared to a case in which the through hole 11 is filled with the metal.

The carbon nanotube may be in the form of a paste and provided in the entire portion or a portion of the through hole 11 using a screen printing method, a spin coating method, or the like. The carbon nanotube paste may be prepared by mixing a carbon nanotube powder with a binder, a solvent, and a dispersing agent in a predetermined ratio, filtering the mixture, and aging the filtered mixture to complete the carbon nanotube paste. The carbon nanotube paste may be prepared by mixing the carbon nanotube powder, the binder, the solvent, and the dispensing agent with each other in the ratio of 40 to 50 wt %, 20 to 30 wt %, 20 to 30 wt %, and 2 to 5 wt %.

For example, an example of the carbon nanotube powder may include a single wall or multiwall carbon nanotube powder, an example of the binder may include polyvinyl butyral, ethyl cellulose, polyester, polyacrylate, or polyvinyl pyrrolidone, an example of the solvent may include ethyl alcohol, toluene, or a mixed solvent of ethyl alcohol and toluene, and an example of the dispersing agent may include glycerine, oilfish, and dioctyl phthalate (DOP).

The conductive nanowire 12 may be formed of a nitride semiconductor or a transparent conductive oxide. The nitride semiconductor may be formed of materials having a compositional formula of AlₓIn_{y}Ga_{(1-x-y)}N (where 0≦x≦1, 0≦y≦1, and 0≦x+y≦1). An example of materials having the above-mentioned compositional formula may include GaN, AlGaN, InGaN, or the like. Meanwhile, the transparent conductive oxide may be formed of at least one of ZnO (zinc oxide), ITO (indium tin oxide), TO (tin oxide), IZO (indium zinc oxide), and ITZO (indium tin zinc oxide).

That is, the conductive nanowire 12 may be formed of a material having a high thermal conductivity. According to the present embodiment, the semiconductor light emitting device 100 includes the light emitting structure 20 formed on the substrate 10 including the through hole 11 formed in the thickness direction and the conductive nanowire 12 provided in at least a portion of the through hole 11, and thus the stress of the semiconductor light emitting device may be alleviated and the heat radiating characteristics thereof may be improved.

FIG. 2 is a cross-sectional view schematically illustrating a semiconductor light emitting device 101 according to an embodiment of the present general inventive concept.

The semiconductor light emitting device 101 according to the present embodiment may include a substrate 110, and a light emitting structure 120 formed on the substrate 110 and including a first conductive semiconductor layer 121, an active layer 122, and a second conductive semiconductor layer 123.

The substrate 110 may include a through hole 111 formed in a thickness direction and a conductive nanowire 112 provided in at least a portion of the through hole 111.

The conductive nanowire 112 may be provided in an entire portion of the through hole 111. In this case, a heat radiation efficiency of the conductive nanowire 112 may be further improved.

First and second electrodes 121a and 123a may be formed on the first and second conductive semiconductor layers 121 and 123 to be electrically connected to the first and second conductive semiconductor layers 121 and 123, respectively.

As illustrated in FIG. 2, the first electrode 121a may be formed on a first surface of the substrate 110 and the light emitting structure 120 may be formed on a second surface of the substrate 110 opposite to the first surface. The second electrode 123a may be formed on the second conductive semiconductor layer 123. A transparent electrode formed of ITO, ZnO, or the like, may be further provided between the second conductive semiconductor layer 123 and the second electrode 123a in order to improve ohmic contact characteristics therebetween.

Since the conductive nanowire 112 provided in the through hole 111 of the substrate 110 has electrical conductivity, the conductive nanowire 112 contacts the first conductive semiconductor layer 121 and the first electrode 121a to be electrically connected thereto. Therefore, the first and second electrodes 121a and 123a may be formed in a vertical direction without removing the substrate 110 for semiconductor growth. In this case, a current flow area may be increased to improve current distribution characteristics.

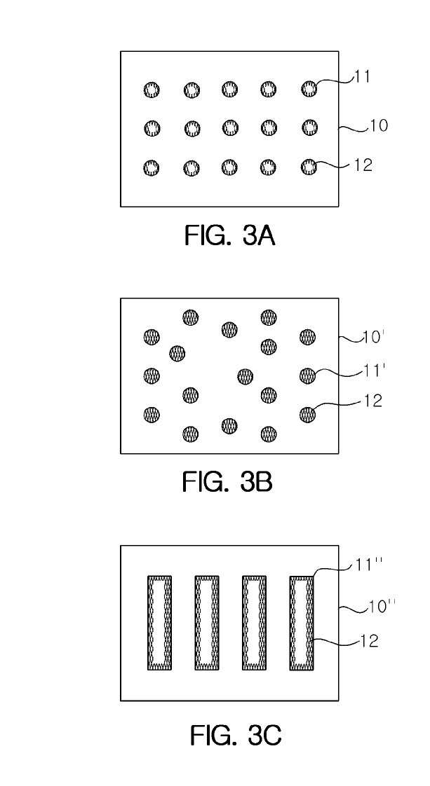

FIGS. 3A through 3C are schematic bottom views illustrating a substrate applicable to a semiconductor light emitting device according to an embodiment of the present general inventive concept. The substrate of FIGS. 3A through 3C may be the substrate 10 of the semiconductor light emitting device 100 of FIG. 1. It is also possible that the substrate of FIGS. 3A through 3C may be the substrate 110 of the semiconductor light emitting device 101 of FIG. 2

Referring to FIGS. 3A through 3C, a plurality of through holes 11 may be formed in the substrate 10 and be disposed to be spaced apart from each other by predetermined intervals. As illustrated in FIG. 3A, the conductive nanowire 12 may be provided in at least a portion of the through hole 11.

As illustrated in FIG. 3B, the conductive nanowire 12 may also be provided in an entire portion of a through hole 11′ of a substrate 10′. The plurality of through holes 11′ may form an irregular pattern. That is, the though holes 11′ may be spaced apart from each other by variable distances. For example, one through hole 11′ is spaced apart from an adjacent through hole 11′ by a first distance and from another through hole 11 by a second distance different from the first distance. In this case, there may be no correlation between the regularity of the pattern of the through hole 11′ and a degree (or amount) of the conductive nanowire 12 provided therein. That is, the conductive nanowire 12 may be provided in the entire portion or a portion of the through holes 11′ having a regular or irregular pattern according to a design or user preference.

As illustrated in FIG. 3C, a plurality of through holes 11″ may have a cylindrical shape, a rectangular shape, or a poly-prismatic shape and form a linear pattern in which the though holes 11″ are disposed to be spaced apart from each other at predetermined intervals in a single direction. However, the present general inventive concept is not limited thereto. It is possible that various shapes can be usable in the semiconductor light emit device as long as the through hole penetrates the substrate.

In addition, although the conductive nanowire 12 is provided in at least a portion of the through hole 11″ in FIG. 3C, the conductive nanowire 12 may be provided in the entire portion or a portion of the through hole 11″, as described above.

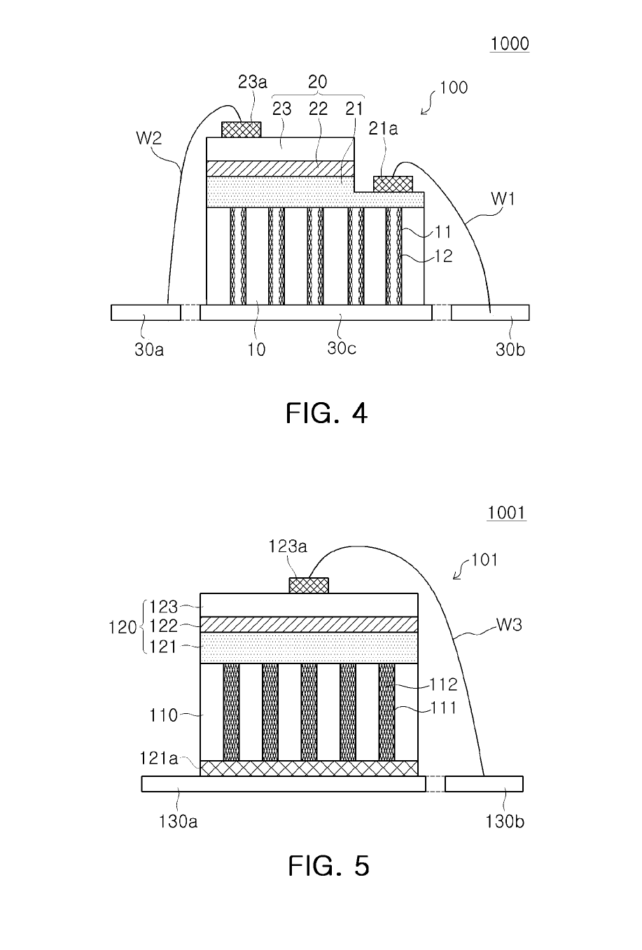

FIG. 4 is a cross-sectional view schematically illustrating a light emitting device package 1000 having a semiconductor light emitting device according to an embodiment of the present general inventive concept.

Referring to FIG. 4, the light emitting device package 1000 according to the present embodiment may include first to third terminal units 30a, 30b, and 30c, and the semiconductor light emitting device 100 may be electrically connected to each of the first and second terminal units 30a and 30b. In this case, the semiconductor light emitting device 100 of FIG. 4 may have the same structure as that of FIG. 1. The first conductive semiconductor layer 21 may be connected to the second terminal unit 30b by a conductive wire W1 connected to the first electrode 21a, and the second conductive semiconductor layer 23 may be connected to the first terminal unit 30a by a conductive wire W2 connected to the second electrode 23a.

The first and second terminal units 30a and 30b may be electrically separated from each other, and the semiconductor light emitting device 100 may be disposed on the third terminal unit 30c electrically separated from the first and second terminal units 30a and 30b. The third terminal unit 30c may serve as a heat radiating terminal and directly contact the substrate 10 including the plurality of through holes 11 and the conductive nanowires 12 provided in the plurality of through holes, whereby heat generated in the light emitting device 100 may be effectively radiated to an outside thereof. When the first, second, and third terminal units 30a, 30b, and 30c are disposed on a terminal unit, an insulation layer may be disposed between the third terminal unit 30a and each of the first and second terminal units 30a and 30b.

FIG. 5 is a cross-sectional view schematically illustrating a light emitting device package 1001 having semiconductor light emitting device according to an embodiment of the present general inventive concept.

Referring to FIG. 5, the light emitting device package 1001 according to the present embodiment may include first and second terminal units 130a and 130b, and the semiconductor light emitting device 101 may be electrically connected to each of the first and second terminal units 130a and 130b. In this case, the semiconductor light emitting device 101 of FIG. 5 may have the same structure as that of FIG. 2. The first conductive semiconductor layer 121 may be directly connected to the first terminal unit 130a by the first electrode 121a formed on the first terminal unit 130a, and the second conductive semiconductor layer 123 may be connected to the second terminal unit 130b by a conductive wire W3 connected to the second electrode 123a. When the first and second terminal units 130a and 130b are disposed on a terminal board, an insulation layer may be disposed between the first and second terminal units 130a and 130b.

In the present embodiment, the conductive nanowire 112 provided in the through hole 111 of the substrate 110 may improve heat radiation efficiency, simultaneously with electrically connecting the first electrode 121a to the first conductive semiconductor layer 121.

Although the conductive nanowire 112 is provided in the entire portion of the through hole 111 as described in the present embodiment, the present general inventive concept is not limited thereto. The conductive nanowire 112 may be provided in only a portion of the through hole 111.

Although not illustrated, the substrate 110 and the first electrode 121a may have a reflective layer interposed therebetween in order to induce light emitted downwardly from the active layer to be emitted upwardly, or the first electrode 121a itself may serve as the reflective layer. The reflecting layer may be formed of a metal having high reflectivity, for example, a material such as silver (Ag), nickel (Ni), aluminum (Al), rhodium (Rh), palladium (Pd), iridium (Ir), ruthenium (Ru), magnesium (Mg), zinc (Zn), platinum (Pt), gold (Au), or the like.

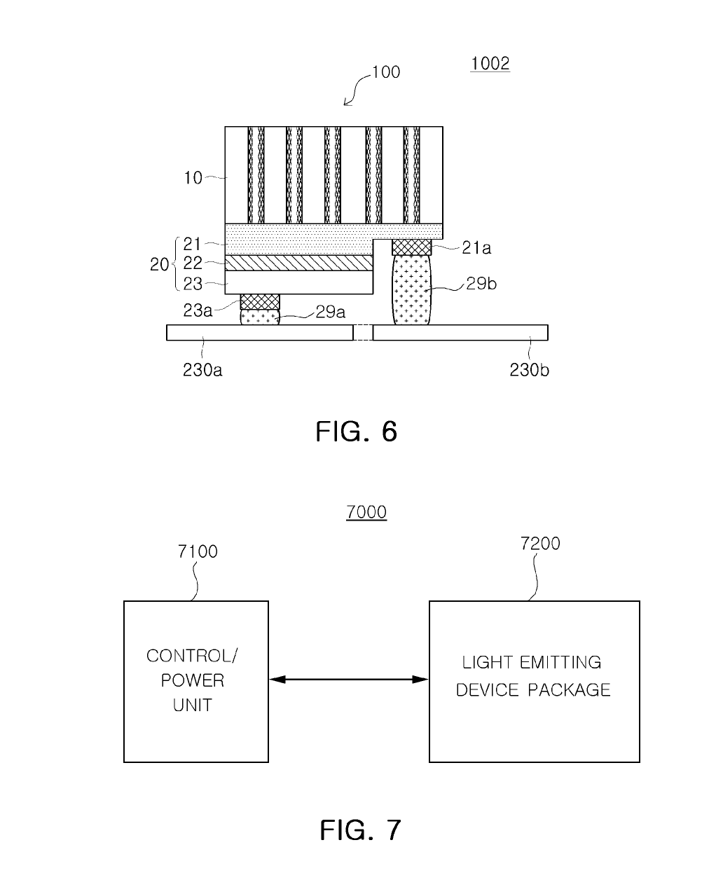

FIG. 6 is a cross-sectional view schematically illustrating a light emitting device package 1002 having a semiconductor light emitting device according to an embodiment of the present general inventive concept.

Referring to FIG. 6, the light emitting device package 1002 according to the present embodiment may include first and second terminal units 230a and 230b, and the semiconductor light emitting device 100 may be electrically connected to each of the first and second terminal units 230a and 230b. The semiconductor light emitting device 100 of FIG. 6 may have the same structure as that of FIG. 1. The first and second electrodes 21a and 21b may directly contact the first and second terminal units 230a and 230b to thereby be electrically connected thereto by first and second conductive materials 29a and 29b, respectively. The first and second conductive materials 29a and 29b may have different lengths or dimensions.

That is, the semiconductor light emitting device 100 may be flip-chip bonded to the first and second terminal units 230a and 230b. In this case, a surface disposed opposite to a surface on which the light emitting structure 20 of the substrate 10 is formed may be provided as a main light emitting surface.

Referring to FIG. 7, an electronic apparatus 7000 may include a control/power unit 7100 and a light emitting device package 7200. The control/power unit 7100 outputs a control signal and a power supply to the light emitting device package 7200 to emit light according to the control signal and the power supply. The light emitting device package 7200 may be the light emitting device package 1000 of FIG. 4, 1001 of FIG. 5, or 1002 of FIG. 6.

As set forth above, in a semiconductor light emitting device according to an embodiment of the present general inventive concept, stress generated due to differences in lattice constants and thermal expansion coefficients between a substrate and a semiconductor layer grown on an upper surface of the substrate is alleviated.

According to an embodiment of the present general inventive concept, a semiconductor light emitting device has improved light distribution and light emitting efficiency.

According to an embodiment of the present general inventive concept, a semiconductor light emitting device has improved heat radiation efficiency and reliability.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor light emitting device comprising:
a substrate having a through hole formed in a thickness direction thereof, and a conductive nanowire provided in at least a portion of the through hole; and
a light emitting structure formed on the substrate and including a first conductive semiconductor layer, an active layer, and a second conductive semiconductor layer.

2. The semiconductor light emitting device of claim 1, wherein the conductive nanowire is formed of at least one of carbon nanotubes (CNT), a nitride semiconductor, and a transparent conductive oxide.

3. The semiconductor light emitting device of claim 2, wherein the carbon nanotubes have a form of a carbon nanotube paste containing a carbon nanotube powder, a binder, and a solvent.

4. The semiconductor light emitting device of claim 2, wherein the nitride semiconductor is at least one of GaN, AlGaN, InGaN, and AlGaInN.

5. The semiconductor light emitting device of claim 2, wherein the transparent conductive oxide is at least one of zinc oxide (ZnO), indium tin oxide (ITO), tin oxide (TO), indium zinc oxide (IZO) and indium tin zinc oxide (ITZO).

6. The semiconductor light emitting device of claim 1, wherein the conductive nanowire covers an inner surface of the through hole, to provide an empty space to at least a portion of the through hole.

7. The semiconductor light emitting device of claim 1, wherein:
the through hole comprises a plurality of through holes; and
the plurality of through holes are spaced apart from each other to form a regular or irregular pattern.

8. The semiconductor light emitting device of claim 7, wherein the plurality of through holes form a linear pattern in which the plurality of through holes are spaced apart from each other in a single direction.

9. The semiconductor light emitting device of claim 1, wherein the through hole has a cylindrical or a poly-prismatic shape.

10. The semiconductor light emitting device of claim 1, wherein the substrate is formed of at least one of sapphire, SiC, Si, MgAl₂O₄, MgO, LiAlO₂, LiGaO₂, and GaN.

11. The semiconductor light emitting device of claim 1, further comprising:
a first electrode formed on the first conductive semiconductor layer exposed by etching the second conductive semiconductor layer, the active layer, and at least a portion of the first conductive semiconductor layer; and
a second electrode formed on the second conductive semiconductor layer.

12. The semiconductor light emitting device of claim 11, wherein a surface disposed opposite to a surface of the substrate on which the light emitting structure is formed is provided as a main light emitting surface.

13. The semiconductor light emitting device of claim 1, further comprising:
a first electrode formed on a surface opposing a surface of the substrate on which the light emitting structure is formed; and
a second electrode formed on the light emitting structure.

14. The semiconductor light emitting device of claim 13, wherein the first electrode contacts the conductive nanowire.

15. The semiconductor light emitting device of claim 14, wherein the conductive nanowire fills a portion of the through hole.

16. The semiconductor light emitting device of claim 13, wherein the conductive nanowire contacts at least a portion of the first conductive semiconductor layer.

17. The semiconductor light emitting device of claim 13, further comprising:
a reflective layer interposed between the substrate and the first electrode.

18. A light emitting device package comprising a terminal unit connected to the semiconductor light emitting device of claim 1.

19. An electronic apparatus comprising a control and power supply unit to output a control signal and a power supply to the light emitting device package of claim 18.

20. A semiconductor light emitting device comprising:
a substrate having one or more through holes formed therein and a conductive nanowire provided in at least a portion of the through hole; and
a light emitting structure formed on the substrate and one ends of the through holes and including a first conductive semiconductor layer, a second conductive semiconductor layer, and an active layer disposed between the first and second conductive semiconductor layers to emit light.
